(19) United States
(12) Patent Application Publication
(10) Pub. No.: US 2007/0289627 A1
(43) Pub. Date: Dec. 20, 2007

(54) Nanoscale solar cell with vertical and lateral junctions

(75) Inventors: Vijay P. Singh, Lexington, KY (US); Suresh Ks Rajaputra, Lexington, KY (US)

Correspondence Address: KING & SCHICKLI, PLLC, 247 NORTH BROADWAY, LEXINGTON, KY, 40507, US

(73) Assignee: University of Kentucky Research Foundation

(21) Appl. No.: 11/471,409

(22) Filed: Jun. 20, 2006

(51) Int. Cl. H01L 31/00

(52) U.S. Cl. 136/264

(57) ABSTRACT

A nanoscale solar cell with vertical and lateral p-n junctions or Schottky barriers includes a light transparent or an opaque substrate with n- and p-type materials thereon. The size of the materials is tailored to optimize their bandgap energies. During use, photons impact the n and p type materials and generated electrons and holes travel through the materials to reach the vertical and horizontal junctions with reduced or neglible recombination loss, and thence to their respective electrodes. Representatively, the n-type material is CdS while the p-type material is CIS. Both are arranged in layers and thicknesses can vary. Fabrication includes forming an alumina template and filling voids with the materials to form n-p junctions. Thereafter, the template is removed and further junctions are formed by filling spaces left by the removed template. Organic semiconductor embodiments of the invention are also contemplated.

### FIELD OF THE INVENTION

Generally, the present invention relates to solar cells and methods for producing same. Particularly, it relates to nanoscale solar cells and their production. In one aspect, nanoscale solar cells include both vertical and lateral junctions operable for creating electron-hole mobility upon photon impact. In another, band gap energy tailoring is accomplished for various materials. Still other aspects relate to particular organic or inorganic materials. Traditional CMOS or other silicon fabrication techniques are contemplated.

### BACKGROUND OF THE INVENTION

It is known for some time to create solar cells for a variety of applications. As demands increase for clean, efficient and economical energy, it is expected that solar cell technologies will continue advancing. As of late, it is even known to create solar cells at the nanoscale. In this regard, photon generated electron-hole pairs have been found to detrimentally recombine during travel before sufficient or sustainable electricity is produced. In other designs, complex fabrication schemes have limited manufacturability. Material selection is also limited thus complicating manufacturing because of toxicity and/or decent ability to make electrical contacts. Still other designs utilize templates but they cannot fairly control its pore randomness or size.

Accordingly, needs exist in the art for simple and reproducible nanoscale solar cells with sustainable electrical outputs, including material sets compatible with human exposure and contact making. Naturally, any improvements should further contemplate good engineering practices, such as relative inexpensiveness, mechanical and electrical stability, low complexity, ease of manufacturing, etc.

### SUMMARY OF THE INVENTION

The above-mentioned and other problems become solved by applying the principles and teachings associated with the hereinafter-described nanoscale solar cell with vertical and lateral junctions. Specifically, apparatus and methods for fabricating include fashioning a substrate with a template and vertically filling voids of the substrate with n- and p-type materials to form junctions. Thereafter, the template is removed and spaces from the removed template are filled with still another material (the same or different than the n- and p-type materials) to form other junctions. In all, a variety of lateral and vertical junctions exist that improve nanoscale solar cell operability. The resultant structure is also fitted with electrodes for operational use. During use, the substrate is arranged to receive light so that photons impact the junctions and electron and holes travel minimal distances through the materials to a respective electrode, thereby creating current.

In a representative embodiment, the nanoscale solar cell includes a light transparent substrate with glass and ITO (indium tin oxide). Thereon, n- and p-type materials are formed. The sizes of the materials are tailored such that the p-type material has a band gap energy, compatible with sunlight, at about 1.5 eV while the n-type material has a band gap energy of about 3.8 eV. Preferably, the n-type material is CdS (cadmium sulfide) and the p-type material is CIS (copper indium diselenide, CuInSe₂, called CIS). Both are arranged in layers on the substrate and formed with conventional thin film techniques. Thicknesses of the layers vary but representatively range about 150 to 4000 nanometers when embodied as CIS laterally adjacent the CdS layer and about 150 to about 4000 nanometers when embodied as CIS vertically adjacent the CdS layer. The CdS layer is about 100 to about 500 nanometers thick on the substrate.

Electrodes include a molybdenum contact above the CIS layer and an ITO layer beneath the CIS and/or CdS layers as part of the substrate. In one instance, the CIS layer also contacts both electrodes. However, the contact between the molybdenum and the CIS layer is conducting while the contact between the CIS layer and the ITO is rectifying, during use.

Methods of fabricating the solar cell include forming an alumina template on the substrate with ordered or uniformly distributed pores or voids about 5 to about 100 nm in diameter. Preferably, the pores exist in the shape of a honeycomb. Vertical filling of the pores occurs first with the CdS and then CIS materials to form an n-semiconductor/p-semiconductor junction between the two. Thereafter, the template is removed and further n-p junctions are formed with at least one of the materials by filling spaces left by the removed template with a third material. In one embodiment, the third material is the same or a different material as one of the prior two materials. Organic embodiments of the invention contemplate substituting CuPc (copper phthalocyanine) for CIS and C₆₀ (fullerene) for CdS. Naturally, other organic and inorganic semi-conducting materials are possible.

These and other embodiments, aspects, advantages, and features of the present invention will be set forth in the description which follows, and in part will become apparent to those of ordinary skill in the art by reference to the following description of the invention and referenced drawings or by practice of the invention. The aspects, advantages, and features of the invention are realized and attained by means of the instrumentalities, procedures, and combinations particularly pointed out in the appended claims.

### BRIEF DESCRIPTION OF THE DRAWINGS

The accompanying drawings incorporated in and forming a part of the specification, illustrate several aspects of the present invention, and together with the description serve to explain the principles of the invention. In the drawings:

FIG. 1 is a diagrammatic view in accordance with the present invention of a nanoscale solar cell with vertical and lateral junctions;

FIGS. 2A-2H are cross sectional views in accordance with the present invention of representative sequential steps for formation of the nanoscale solar cell of FIG. 1; and

FIG. 3 is a top view picture in accordance with the present invention of the template of FIG. 2C.

### DETAILED DESCRIPTION OF THE PREFERRED EMBODIMENTS

In the following detailed description of the preferred embodiments, reference is made to the accompanying drawings that form a part hereof, and in which is shown by way of illustration, specific embodiments in which the invention may be practiced. These embodiments are described in sufficient detail to enable those skilled in the art to practice the invention and like numerals represent like details in the various figures. Also, it is to be understood that other embodiments may be utilized and that process, mechanical, electrical and/or other changes may be made without departing from the scope of the present invention. In accordance with the present invention, an improved nanoscale solar cell with lateral and vertical junctions is hereinafter described.

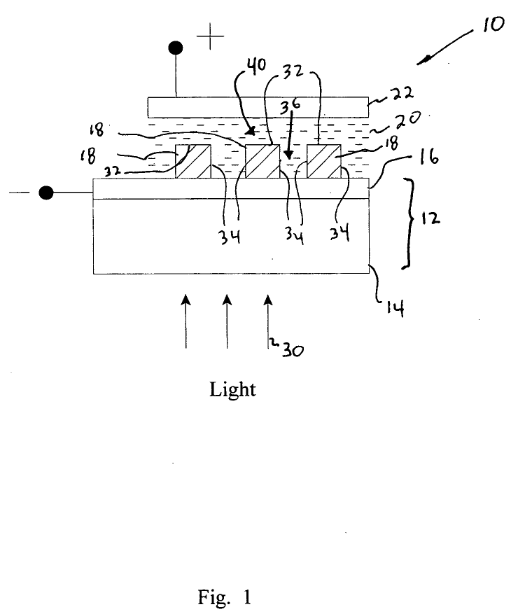

With reference to FIG. 1, a nanoscale solar cell of the invention is given generically as 10. It includes a substrate 12, first and second n- and p-type materials 18, 20 on the substrate and a contact 22. Alternatively, the sequence n-p is reversed to p-n, wherein the p-type material and n-type material are layers 18 and 20, respectively. During use, interfaces between the materials serve as pluralities of junctions 32, 34. These junctions help separate the electrons and holes and propel them in opposite directions. In the case or inorganic semiconductor solar cells, electrons and holes generated by absorption of light 30 in the semiconductor materials are propelled in opposite directions by the electric field at the p-n junction. In the case of organic semiconductor solar cells, excitons generated by absorption of light in the semiconductor materials are split into electrons and holes at the electron donor/electron acceptor interface and propelled in opposite directions after being separated. In turn, the electrons and holes from various junctions travel through the semiconducting materials to the respective (+) or (−) electrode. After separation and or propulsion at the junction, the holes travel through the p-type material to contact 22 while electrons travel through the n-type material to an ITO contact layer 16 forming a portion of the substrate. Because of the relative sizes of the materials, e.g., nanoscale, the electrons (and holes) travel a very short distance in the p-type material and holes travel a very short distance in the n-type material; thus adverse recombination of the electrons and holes is avoided or minimized. Because of this advantage, as well as the advantage of band gap tailoring (to a value close to 1.5 eV, described below, which is ideal for our solar system) in these nanostructured semiconductors, higher short-circuit densities and higher open circuit voltages are expected. For the case of particular materials involving CdS/CIS (described below), heterojunctions short circuit current density (J_{SC}) in excess of about 40 milliamperes/cm² and open circuit voltage (V_{OC}) in excess of about 1 volt can be expected.

With more specificity, the substrate 12 of the invention representatively includes both a glass layer 14 and an overlying ITO layer 16. In thickness, the glass is relatively thick at about 1/16^{th} of an inch while the ITO is relatively thin at about 0.15 micrometers. While one or more other layers can be used in addition to or in lieu of these layers, the other layers need to embody characteristics for passing visible light. In this regard, plastics or other materials are contemplated. In all, sunlight is the primary light contemplated for use with the solar cell, although the above-mentioned advantages will be of value in many other devices like photodetectors for detecting single or multiple wavelengths of radiation in the ultraviolet-visible-infrared range.

On the substrate, the n- and p-type materials include either organic or inorganic layers of semiconductors. They are also preferably uniformly thick where formed. In one instance, they embody CdS (n-type) and CIS (p-type). In another, they are CuPc (electron-donor) and C₆₀ (electron-acceptor). In either, they cumulatively range in thickness from about 300 to about 4500 nanometers on the substrate. Also, the thickness of the p-type material in region 36 is about 200 to about 4000 nanometers thick and ranges from the ITO layer 16 to the contact 22. The thickness of the p-type material in region 40, on the other hand is about 100 to about 3900 nanometers thick. Of course, other thicknesses are possible and all are embraced herein. Other arrangements of materials are also possible provided both vertical and lateral junctions between the materials exist.

Regarding the contact 22, it is preferably molybdenum. Alternatively, it is gold. In thickness, it is about 0.5 micrometers thick. It is also preferred that the layer is uniformly thick throughout. Its use is that of an electrode and such is well known.

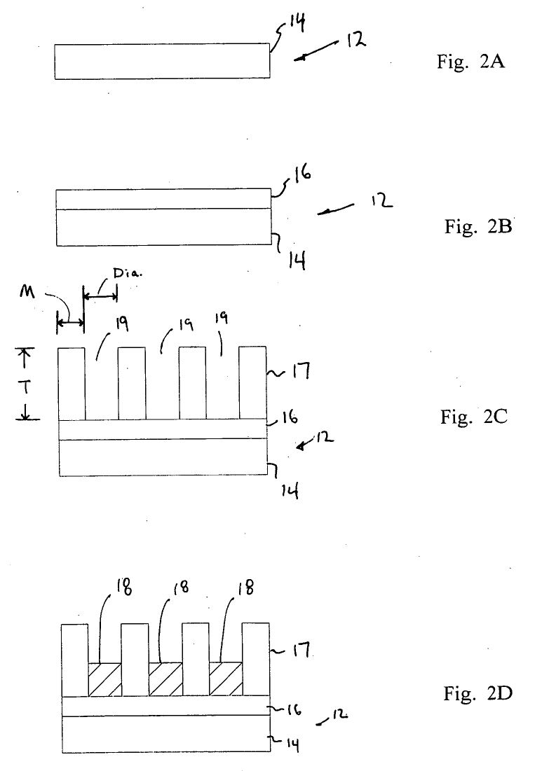

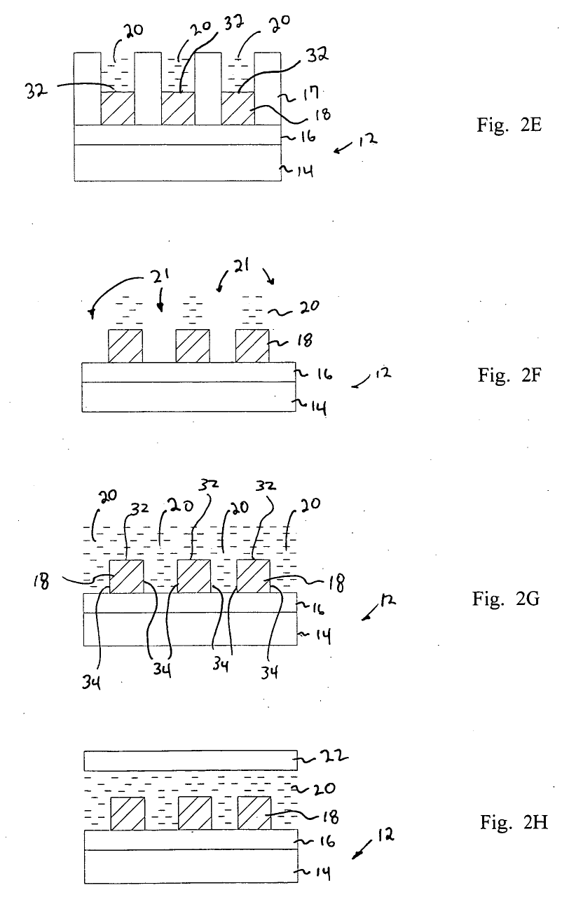

With reference to FIGS. 2A-2H, the process steps for forming the nanoscale solar cell are described. Namely, FIG. 2A begins the process by providing or otherwise forming a substrate 12. In one instance it is a layer of glass on the order of about 1/16^{th} of an inch thick. In another, it is any visible light transparent layer of any thickness. In this regard, suitable plastics include any of the following: transparent plastics coated with a conductive oxide like ITO. In FIG. 2B, the substrate further includes an ITO layer 16 on the glass. Its formation representatively occurs through deposition, evaporation, sputtering, spray pyrolysis, or other thin film processes. Alternate embodiments contemplate a transparent material useful in forming an electrode.

In FIG. 2C, the substrate 12 is patterned with a template 17 that will be used to form subsequent layers and then later removed from the resultant nanoscale solar cell. In one embodiment, the template is a layer of alumina (Al₂O₃) uniformly ordered with pluralities of pores or voids 19 uniformly distributed over an area of about 25 cm². In fabrication, a relatively uniformly thick aluminum layer is sputtered or evaporated on the substrate 12 and a current flow in a chemical bath of oxalic acid (H₂C₂O₄) is used to create the pores or voids. To achieve appropriate diameters and spacing of the pores, various anodizing conditions have been developed and more are contemplated. In one example, a two step process includes: first, a 2 minute anodization in oxalic acid followed by a 2 minute etching in phosphoric acid; and second, application of current for about 25 minutes at a current density, in the chemical bath, of about 30 A/m² with voltages across electrodes in the bath at about a relatively constant 40 volts.

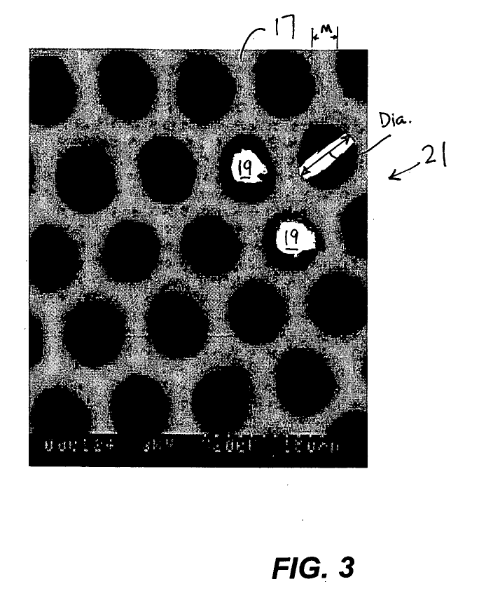

With reference to FIG. 3, an actual resultant alumina template is shown in a top view orthogonal to FIG. 2C. As seen, the template typifies a honeycomb pattern 21 having alternating voids 19 and alumina material 17. It is relatively ordered and extends over an area of about 25 cm². Representatively, each void has a diameter (Dia.) of about 60 nanometers. Referring back to FIG. 2C, its thickness T is about 4000 nanometers with material M in the honeycomb being walled at about 10 to about 100 nanometers wide.

In other embodiments, however, the template is titania (TiO₂). These, however, have a thickness T of about 1000 nanometers, material walls M of about 40 to about 50 nanometers and pore diameters Dia. of about 10 to about 100 nanometers. In still other embodiments, other templates like tin oxide are contemplated.

With reference to FIG. 2D, portions of the pores or voids of the template 17 are vertically filled with the n-type material. In this instance, the n-type material is CdS. In others, it is n-Si or ZnO or materials having characteristics of an n-type semiconductor. Regardless, it is preferred to be electrochemically deposited. In a typical experiment for electro-depositing CdS into an AAO template, a solution composed of 0.055M CdCl₂ and 0.19M elemental sulfur is used. Temperature is maintained at about 120° C. and electro-deposition occurs by applying a DC voltage (variable between about 12-30V) between a working electrode and a platinum counter electrode. Naturally, different DC voltages and deposition times are used depending on the thickness of the template and the amount of filling required. In other embodiments, however, evaporation, lithography, sputtering, etc. are contemplated.

Because the size of the pores of the template is on the nanoscale, the CdS is similarly nano-scaled. In turn, its band gap energy increases over larger samples of the same material and is tailored to have a band gap energy on the order of about 3.8 eV instead of 2.4 eV for large crystallite structures. In this manner, additional photons (with energies in the range 2.4 eV-3.8 eV) from the incident light are able to pass through the layer of CdS material, e.g., which serves as a window layer.

In FIG. 2E, a second material 20 of opposite type, or p-type material, is layered vertically on the first material of n-type 18. It creates a junction 32 at the interface of the two materials and an electric field is created at and near the junction. In use, electrons (after generation by the absorption of photons in the semiconductor materials) that reach the junction field are propelled toward the CdS. Similarly, holes that reach the junction field are propelled toward the p-type material and electrode. In composition, the p-type material is representatively CIS. Again, because of the small size of the voids of the template, the CIS (which normally has a band gap energy of about 1.0 eV) is similarly small and tailored to have a band gap energy of about 1.5 eV. In turn, a band gap energy of about 1.5 eV is essentially ideal for a solar cell operating on light from the sun. However, other materials could be selected. To name a few, it is contemplated that C₆₀ will yield positive results when used with CuPc material as an electron donor material. Still other embodiments contemplate other p-type materials like Cu₂S.

Similar to the first material, the second material 20 is deposited, evaporated, sputtered, etc. Also, it is expected that when CdS and CIS are used together, the effective energy band gap of both materials, due to quantum confinement in nanoscale pores, is such that the band gap of the CdS will allow high energy photons to pass through, making it a better window material, while an increase in the CIS band gap will make it optimal for the solar spectrum, and should lead to a higher current on the electrodes, and higher efficiency.

Thereafter, with reference to FIG. 2F, the template 17 is removed thereby leaving spaces 21 between the vertically stacked n- and p-type materials 18, 20. Preferably, removal of the template occurs by way of selective chemical etching of the alumina only. In this regard, a KOH bath or other may be used.

Once removed, FIG. 2G depicts the filling of the spaces with a third material, especially more of the second or p-type material 20. Alternatively, more of the first n-type material is used. In this manner, more interfaces between the first and second materials are created. Particularly, interfaces for n-p junctions now exist at element 34 in addition to those junctions at element 32. In this manner, the relative size (area) of the p-n junctions is increased over that of FIG. 2F and further electron-hole separation is realized. Also, it is possible that the p-type material in the regions 36 (FIG. 1) laterally adjacent the n-type material, where spaces 21 (FIG. 2F) of the removed template were filled, will be formed under different conditions than that of the p-type material vertically adjacent or above the n-type material in region 40 (FIG. 1).

Lastly, FIG. 2H shows a contact 22 formed on the nanoscale solar cell 10 and it serves as one of the electrodes. In one embodiment, it is molybdenum with a substantially uniform thickness of about 500 nanometers. In other embodiments, its composition is gold. Formation of the contact occurs similar to the other layers via sputtering, deposition, evaporation, etc. Also, skilled artisans will observe that the second material 20 extends the entirety of the distance from the substrate to the contact. However, a short does not exist during use because it is expected that the contact between the second material 20 and the contact 22 will be conducting while the contact between the second material 20 and the substrate 12, especially the ITO layer 16, will be rectifying.

In any orientation, certain advantages of the invention over the prior art are readily apparent. For example, in solar cells of nanoscale dimensions, band gap energies of active semiconductor materials can be tailored to be compatible with the energies of photons in sunlight. Also, due to the nanoscale porous structure of the solar cell formed with a fairly uniform template, the distance that a photo-excited electron must travel within their life time is reduced to less than 50 nm. Recombination of the electrons and holes is then fairly prevented or reduced. Less intuitively, the p-n junction area between the p- and n-type materials is enlarged (typically by a factor 10) relative to the prior art because of both vertical and lateral junctions existing in the design of the invention. In turn, this reduces the loss of current due to electron hole combinations prior to separation and or propulsion in opposite directions. Another benefit is light scattering, which boosts the light absorbing capacity of the thin film layers of the solar cell. More intuitively, the materials for the solar cell can be selected to be more compatible with lengthy and direct human exposure while still yielding good contact making and cell performance. Still other advantages are realized because traditional CMOS or other silicon fabrication techniques can be used in forming the nanoscale solar cell. This adds robustness and tends to lower manufacturing costs. Still other advantages are readily apparent to skilled artisans.

Finally, one of ordinary skill in the art will recognize that additional embodiments are also possible without departing from the teachings of the present invention. This detailed description, and particularly the specific details of the exemplary embodiments disclosed herein, is given primarily for clarity of understanding, and no unnecessary limitations are to be imported, for modifications will become obvious to those skilled in the art upon reading this disclosure and may be made without departing from the spirit or scope of the invention. Relatively apparent modifications, of course, include combining the various features of one or more figures with the features of one or more of other figures.

What is claimed:

1. A solar cell, comprising:
a substrate including CdS and CIS thereon; and
a plurality of vertical and lateral junctions at interfaces between the CdS and CIS.

2. The solar cell of claim 1, wherein the substrate includes indium tin oxide.

3. The solar cell of claim 1, wherein the substrate includes glass.

4. The solar cell of claim 1, wherein the CIS is tailored in size to have a band gap energy of about 1.5 eV.

5. The solar cell of claim 1, wherein the CdS is tailored in size to have a band gap energy of about 3.8 eV.

6. The solar cell of claim 1, further including a contact on the CIS.

7. The solar cell of claim 6, wherein the contact is molybdenum.

8. The solar cell of claim 1, wherein the CdS and CIS are layers directly on the substrate.

9. The solar cell of claim 8, wherein the CdS layer is about 100 to about 500 nanometers thick.

10. The solar cell of claim 8, wherein the CIS layer is about 150 to about 4000 nanometers thick above the CdS.

11. The solar cell of claim 8, wherein the CIS layer is about 150 to about 4000 nanometers thick laterally adjacent the CIS layer.

12. The solar cell of 8, wherein the CIS layer is both laterally and vertically adjacent the CdS layer.

13. The solar cell of claim 12, wherein the CIS layer laterally adjacent the CdS layer extends between a contact and an ITO layer.

14. The solar cell of claim 8, further including an electrode on the CIS layer.

15. The solar cell of claim 14, wherein the CIS layer contacts both the electrode and the substrate, the contact between the electrode and the CIS layer being conducting and the contact between the CIS layer and the substrate being rectifying during use.

16. The solar cell of claim 14, wherein the CIS and the CdS layer are between the substrate and the electrode.

17. A nanoscale solar cell, comprising:
a substrate including an n-type material and a p-type material thereon;
a plurality of vertical and lateral p-n junctions at interfaces between the n- and p-type materials, wherein the p-type material is tailored in size to have an effective band gap energy of about 1.5 eV and the substrate is arranged to receive light so that photons can impact n- and p-type materials and the interfaces.

18. The solar cell of claim 17, wherein the n-type material is CdS and the p-type material is CIS and the materials are arranged in layers on the substrate.

19. The solar cell of claim 18, wherein the CIS layer is both laterally and vertically adjacent the CdS layer.

20. The solar cell of claim 19, wherein the CIS layer is about 150 to about 4000 nanometers thick laterally adjacent the CIS layer and about 150 to about 4000 nanometers thick vertically adjacent the CdS layer, the CdS layer being about 100 to about 500 nanometers thick on the substrate.

21. The solar cell of claim 20, further including an electrode on the CIS layer.

22. The solar cell of claim 21, wherein the CIS layer contacts both the electrode and the substrate and the contact between the electrode and the CIS layer is conducting and the contact between the CIS layer and the substrate is rectifying during use.

23. A method of fabricating a nanoscale solar cell, comprising:
forming a template on a substrate;
vertically filling voids of the template with a plurality of materials to form an n-p junction or a schottky barrier between the materials;
removing the template; and
forming further junctions or barriers with at least one of the materials by filling spaces left by the removed template with a third material, the third material being a same or different material as one of the plurality of materials.

24. The method of claim 23, further including tailoring a size of one of the materials to have an effective band gap energy of about 1.5 eV.

25. The method of claim 23, further including tailoring a size of one of the materials to have an effective band gap energy of about 3.8 eV.

26. The method of claim 25, further including forming an electrode with the one of the materials.

27. The method of claim 23, wherein the vertical filling further includes layering a CdS layer in a thickness of about 100 to about 500 nanometers.

28. The method of claim 23, wherein the vertical filling further includes layering a CIS layer in a thickness of about 150 to about 4000 nanometers.

29. A method of fabricating a nanoscale solar cell, comprising:
providing a light transparent substrate;
forming a honeycomb template about 1000 nm thick on the substrate with voids in the honeycomb template being substantially uniformly distributed on the order of about one per every 10 to every 100 nm;
vertically filling the voids in a direction away from the substrate with a first n-type material and a second p-type material on top of one another to form a p-n junction between the materials;
removing the template; and
forming further p-n junctions with at least one of the first and second materials by filling spaces left by the removed template with a third material, the third material being a same or different material as the first and second materials.

30. The method of claim 29, further including tailoring a size of the second p-type material to have an effective band gap energy of about 1.5 eV.

31. The method of claim 29, further including tailoring a size of the first n-type material to have an effective band gap energy of about 3.8 eV.

32. The method of claim 29, further including forming an electrode with one of the first or second materials.

33. The method of claim 29, wherein the vertical filling further includes layering a CdS layer in a thickness of about 100 to about 500 nanometers.

34. The method of claim 29, wherein the vertical filling further includes layering a CIS layer in a thickness of about 100 to about 4000 nanometers.

35. A solar cell, comprising:
a substrate including CuPC and C₆₀ thereon; and
a plurality of vertical and lateral junctions at interfaces between the CuPC and C₆₀.
